(19) United States
(12) Patent Application Publication
(10) Pub. No.: US 2015/0093861 A1
(43) Pub. Date: Apr. 2, 2015

(54) METHOD FOR THE FORMATION OF CMOS TRANSISTORS

(71) Applicant: STMicroelectronics, Inc., Coppell, TX (US)

(72) Inventors: Nicolas Loubet, Guilderland, NY (US); Qing Liu, Guilderland, NY (US); Prasanna Khare, Schenectady, NY (US)

(73) Assignee: STMICROELECTRONICS, INC., Coppell, TX (US)

(21) Appl. No.: 14/042,884

(22) Filed: Oct. 1, 2013

(51) Int. Cl. H01L 21/84

(52) U.S. Cl. CPC H01L 21/84
USPC 438/154

(57) ABSTRACT

An SOI substrate includes first and second active regions separated by STI structures and including gate stacks. A spacer layer conformally deposited over the first and second regions including the gate stacks is directionally etched to define sidewall spacers along the sides of the gate stacks. An oxide layer and nitride layer are then deposited. Using a mask, the nitride layer over the first active region is removed, and the mask and oxide layer are removed to expose the SOI substrate in the first active region. Raised source-drain structures are then epitaxially grown adjacent the gate stacks in the first active region and a protective nitride layer is deposited. The masking, nitride layer removal, and oxide layer removal steps are then repeated to expose the SOI in the second active region. Raised source-drain structures are then epitaxially grown adjacent the gate stacks in the second active region.

### TECHNICAL FIELD

The present invention relates to integrated circuits and, in particular, to a process for the formation of complementary metal oxide semiconductor (CMOS) transistors.

### BACKGROUND

Increased circuit density is a critical goal of integrated circuit design and fabrication. In order to achieve higher density, a downscaling of the transistors included within the circuit is effectuated. Such downscaling is typically achieved by shrinking the overall dimensions (and operating voltages) of the transistors. This shrinking cannot, however, be achieved at the expense of electrical performance. This is where the challenge arises: how to reduce transistor dimensions while maintaining the electrical properties of the device.

Conventional planar FET devices formed on bulk semiconductor substrates are quickly reaching their downscaling limit. Integrated circuit designers are accordingly turning towards new process technologies, new supporting substrates and new transistor configurations to support smaller and smaller transistor sizes without sacrificing transistor performance. One such new supporting substrate technology concerns the use of silicon on insulator (SOI) substrates to support the fabrication of transistor devices of smaller size. An SOI substrate is formed of a top semiconductor (for example, silicon or silicon-germanium) layer over an insulating (for example, silicon dioxide) layer over a bottom semiconductor (for example, silicon) substrate layer. Further substrate development has reduced the thickness of the intervening insulating layer to about 50 nm to produce a substrate for use in transistor fabrication that is referred to as an extremely thin silicon on insulator (ETSOI) substrate. Still further substrate development has reduced the thicknesses of all substrate layers to produce a substrate for use in transistor fabrication that is referred to an ultra-thin body and buried oxide (UTBB) substrate where the thickness of the intervening insulating layer is about 25 nm (or less) and the thickness of the top semiconductor layer is about 5 nm to 10 nm.

In a transistor fabricated using any one of the available types of SOI substrates, the channel region of the transistor is formed in the top semiconductor layer (that layer may, for example, be fully depleted for the purpose of controlling short channel effects). A gate stack is fabricated above the channel region and insulated from the channel by a gate oxide. The source and drain regions are provided on either side of the gate and channel, and are typically of the raised source/drain type separated from the conductive material of the gate stack by sidewall spacers. The threshold voltage of the fabricated transistor may be tuned through the application of a back bias to the bottom semiconductor substrate layer.

To isolate adjacent transistors from each other, it is known in the art to use shallow trench isolation (STI) techniques. With transistors formed on a UTBB substrate, for example, the STI structure is preferably a high aspect ratio structure (for example, having a ratio of about 1:10) which extends through both the ultra-thin top semiconductor layer and the thinner intervening insulating layer to reach into the bottom semiconductor substrate layer. In a preferred implementation, the bottom of the STI structure reaches a depth about 150 nm below the intervening insulating layer.

When forming an STI structure, a trench is defined adjacent the transistor active region. The trench typically extends through the top semiconductor layer and the intervening insulating layer and into the bottom semiconductor substrate layer. The trench may be lined and then filled with an insulating material such as silicon dioxide to a level above the top surface of the ultra-thin top semiconductor layer.

Different transistor active regions are typically provided on the wafer to support the fabrication of transistors of different conductivity type such as with CMOS integrated circuits. The transistor active regions are separated from each other by the STI structure. The gate structures and source/drain regions are then fabricated in the active region to define individual transistors.

It is common, however, for certain steps of the fabrication process to be separately applied to the regions of the wafer associated with fabrication of the p-type transistors and n-type transistors. For example, separately applied spacer layers are often used in different active regions. Additionally, certain processes, such as etches, may be separately applied to different active regions. The separated handling of fabrication process steps in different active regions can produce inconsistent structures for the p-type transistors and n-type transistors. For example, the thickness of a layer deposit may not be consistent in different active regions. Still further, the etching performed may affect a common layer differently in different active regions. As a result, the physical characteristics of certain transistor structures, such as spacer layers, channels, source/drain regions, etc., may undesirably be different between a p-type transistor and an n-type transistor formed in different active regions of a CMOS circuit on a common SOI substrate.

There is a need in the art for a fabrication process which addresses the foregoing concerns. More specifically, a need exists for an improved fabrication process designed to minimize differences in structure between fabricated p-type transistors and n-type transistors supported by an SOI substrate.

### SUMMARY

In an embodiment, a method comprises: forming shallow trench isolation structures on a silicon on insulator (SOI) substrate to define for a wafer a first active region for first conductivity type transistor fabrication separated from a second active region for second conductivity type transistor fabrication; forming a first gate stack over a top semiconductor layer of the SOI substrate in the first active region and a second gate stack over the top semiconductor layer of the SOI substrate in the second active region; conformally depositing a spacer layer on the wafer over the first and second active region; anisotropically etching the wafer to remove the spacer layer except from sidewalls of the first and second gate stacks so as to define sidewall spacers on said first and second gate stacks; forming an oxide layer on the wafer to cover the SOI substrate, shallow trench isolation structures, sidewall spacers and gate stacks; and forming a nitride layer on the wafer over the oxide layer.

In an embodiment, a method comprises: forming a first gate stack over a top semiconductor layer of a SOI substrate in a first active region; forming a second gate stack over the top semiconductor layer of the SOI substrate in a second active region; conformally depositing a spacer layer over the first and second active region; anisotropically etching to remove the spacer layer except from sidewalls of the first and second gate stacks so as to define sidewall spacers on said first and second gate stacks; forming an oxide layer to cover the SOI substrate, sidewall spacers and gate stacks; and forming a nitride layer over the oxide layer.

### BRIEF DESCRIPTION OF THE DRAWINGS

For a better understanding of the embodiments, reference will now be made by way of example only to the accompanying figures in which:

FIGS. 1-18 illustrate process steps in the formation of CMOS transistors on a silicon on insulator (SOI) substrate (for example, an ultra-thin body and buried oxide (UTBB) substrate) with shallow trench isolation (STI) between active regions.

### DETAILED DESCRIPTION OF THE DRAWINGS

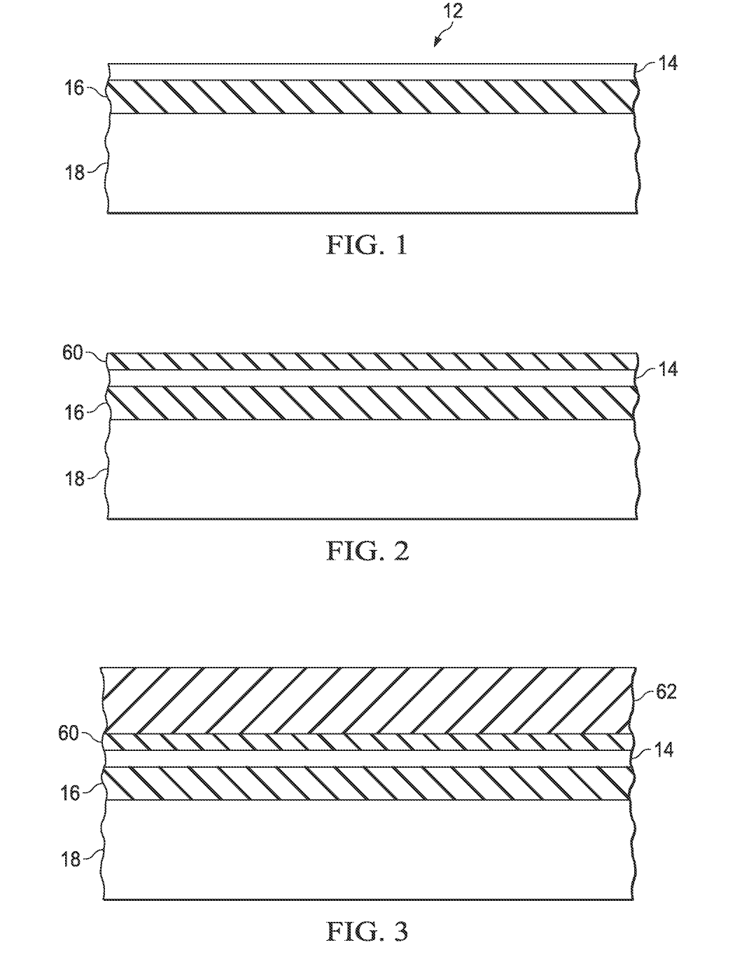

FIG. 1 shows a silicon on insulator (SOI) wafer 12 of a conventional type. For example, the wafer may comprise an ultra-thin body and buried oxide (UTBB) substrate. The substrate wafer 12 comprises a top semiconductor (for example, silicon or silicon-germanium) layer 14 over an insulating (for example, silicon dioxide) layer (BOX) 16 over a bottom semiconductor (for example, silicon) substrate layer 18. With a UTBB substrate, for example the top semiconductor layer 14 may have a thickness of 5 nm to 10 nm, the insulating layer 16 may have a thickness of 10 nm to 30 nm, and the bottom semiconductor substrate layer 18 may have a thickness of 100 microns to 800 microns. The top semiconductor layer 14 and bottom semiconductor substrate layer 18 may be doped as appropriate for the integrated circuit application. The thickness of the top and bottom semiconductor layers 14 and 18 may be tuned (for example, through the use of a thinning operation) as needed for the integrated circuit application. The top semiconductor layer 14 may, in a preferred embodiment, have a fully depleted (FD) configuration. Although a UTBB substrate is preferred, it will be understood that the substrate could comprise a silicon on insulator (SOI) substrate of any configuration including an extremely thin silicon on insulator (ETSOI) substrate.

FIG. 2 shows the deposit of a pad oxide layer 60 over the top semiconductor layer 14 of the UTBB substrate. The pad oxide layer 60 is typically formed of silicon dioxide (SiO₂) and is deposited using a chemical vapor deposition (CVD) process well known to those skilled in the art. The layer 60 may have a thickness of 3 nm to 10 nm.

FIG. 3 shows the deposit of a silicon nitride (SiN) layer 62 over the pad oxide layer 60 which is deposited using a chemical vapor deposition process well known to those skilled in the art. The layer 62 may have a thickness of 30 nm to 80 nm.

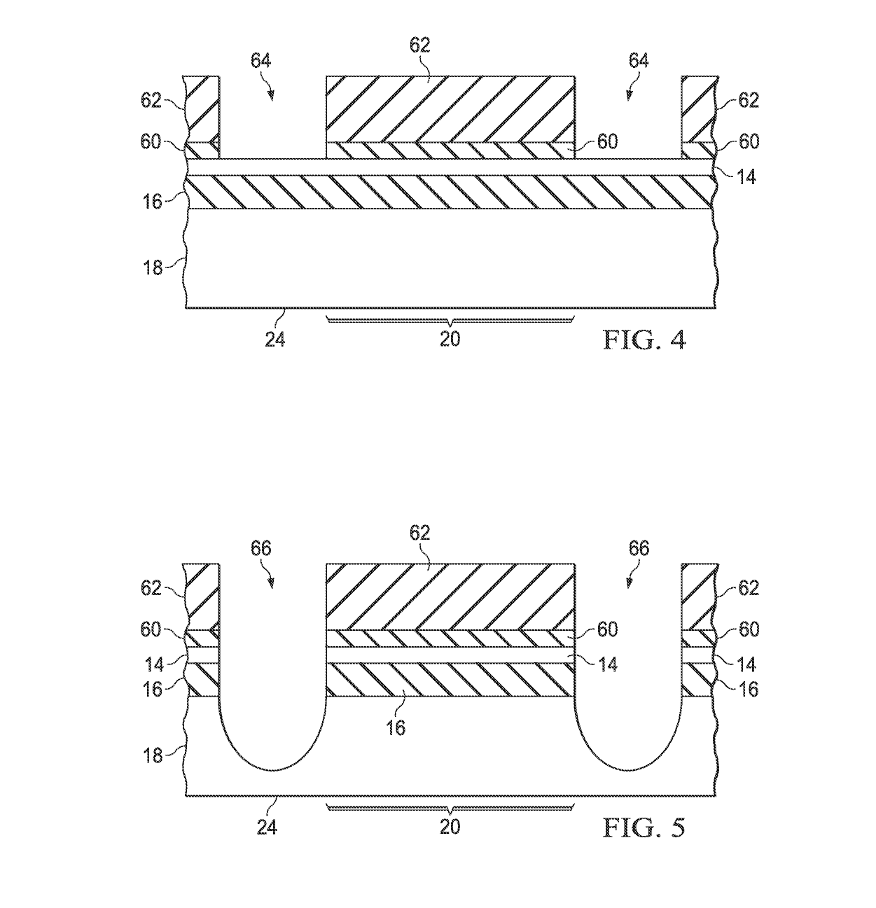

A lithographic process as known in the art is then used to form openings 64 in the silicon nitride layer 62 and pad oxide layer 60 (which together define a SiN/SiO₂ hard mask as known in the art). The openings 64 extend down to reach at least the top surface of the top semiconductor layer 14 of the UTBB substrate. The result of the lithographic process is shown in FIG. 4. The openings 64 are associated with the formation of shallow trench isolation structures and the area between the shallow trench isolation structures is defined as the location of the active region 20. In plan view, the openings 64 may have on ring-like shape sized to surround the active region 20 and thus define the size and shape of the active region.

A high pressure directional etch process as known in the art is then performed through the openings 64 to form a trench 66 extending fully through the top semiconductor layer 14 and insulating layer 16 of the substrate 12. The trench 66 further penetrates into at least a portion of bottom semiconductor substrate layer 18. The etch may comprise an RIE process as known in the art. The result of the directional etch process is shown in FIG. 5. Although not specifically illustrated in FIG. 5, in an embodiment the trench 66 may extend fully through the bottom semiconductor substrate layer 18 to reach a bottom surface 24 of the substrate 12.

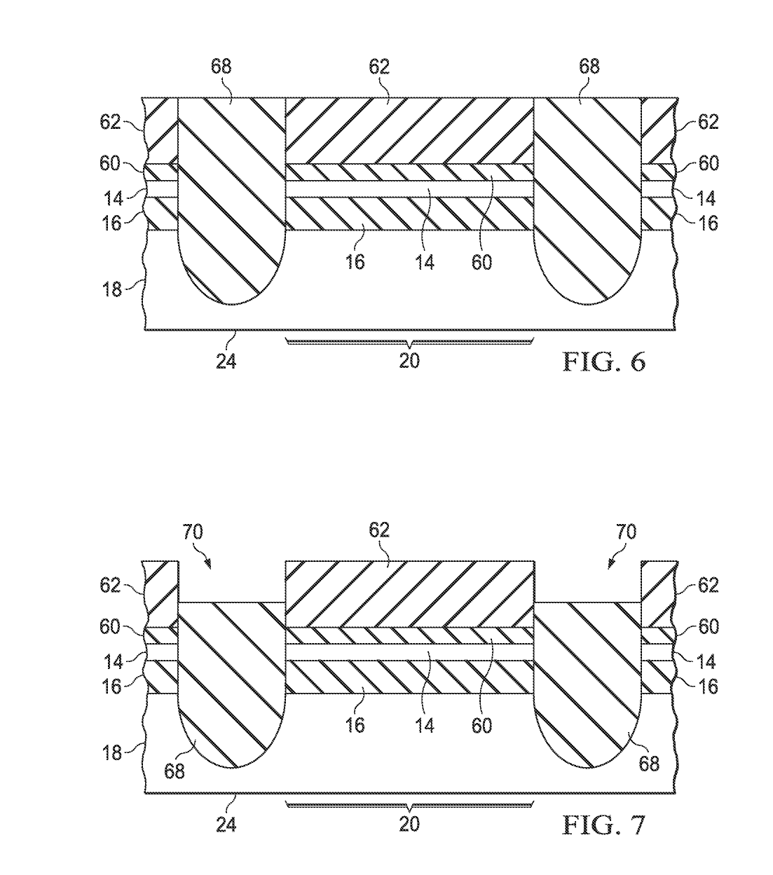

A process is then performed to fill each trench 66 with a shallow trench isolation structure 68. The shallow trench isolation structure 68 is illustrated in FIG. 6 in a generic fashion, and thus details of all included layers, liners and fill materials are not specifically illustrated. Additionally, details concerning the fabrication process for filling the trench 66 with the shallow trench isolation structure 68 are not provided herein, but rather are considered to be well known to those skilled in the art. The fabrication process for making the shallow trench isolation structure 68 may comprise the process illustrated in U.S. application for patent Ser. No. 13/907,237 filed May 31, 2013 (the disclosure of which is incorporated by reference). In an embodiment, the trench 66 may be lined with insulating material and a high aspect ratio deposition process (HARP) known to those skilled in the art may be used to fill the trench 66 with an insulating silicon dioxide (SiO₂) material. Following a thermal anneal process at a temperature of 1050-1100 degrees Centigrade, the wafer is polished to provide a flat surface stopping at the layer 62.

A deglazing process as known in the art is then performed to recess to a desired depth the shallow trench isolation structure 68 by removing any liner and fill material as indicated at reference 70. The result of the deglazing process is shown in FIG. 7. The deglazing process may utilize hydrofluoric (HF) acid and a HF acid diluted by ethylene glycol (HFEG) solution to both clean and etch inside the STI structure. The hydrofluoric (HF) acid removes the fill material (for example, silicon dioxide (SiO₂)) while the HFEG solution removes the liner material (for example, silicon dioxide (SiO₂) and silicon nitride (SiN)). The desired depth of the deglaze is preferably shallower that the thickness of the layer 62.

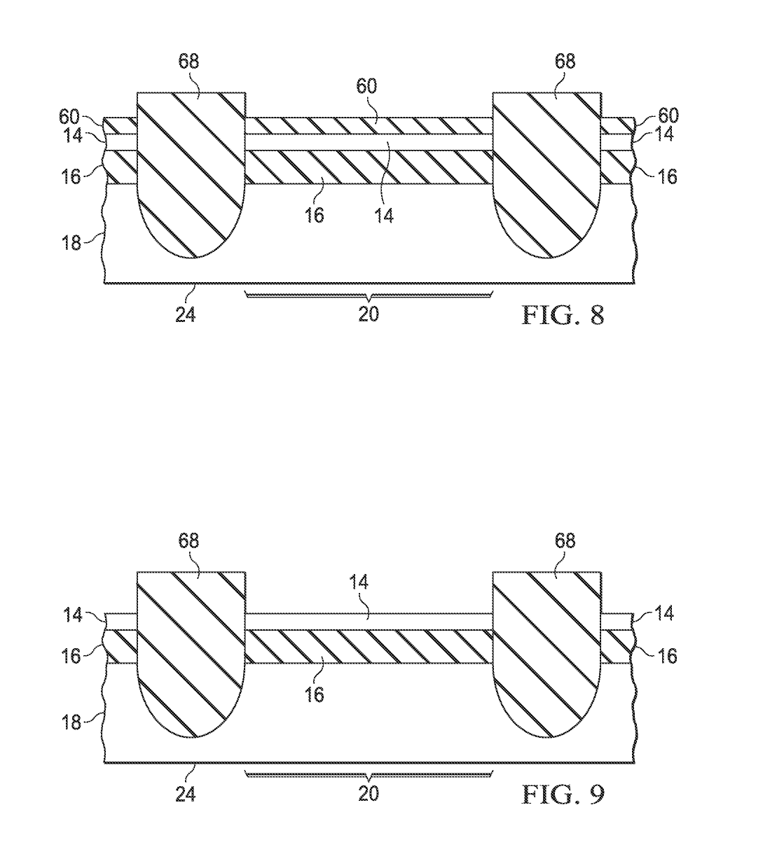

A hot phosphoric acid etch process as known in the art is then used to remove the silicon nitride layer 62 all the way down to the underlying pad oxide layer 60 made of silicon dioxide (SiO₂) material. The result of the hot phosphoric acid etch process is shown in FIG. 8.

A hydrofluoric (HF) acid etch process as known in the art is then used to remove the pad oxide layer 60 made of silicon dioxide (SiO₂) material all the way down to the underlying top semiconductor layer 14. The result of the hydrofluoric (HF) acid etch process is shown in FIG. 9.

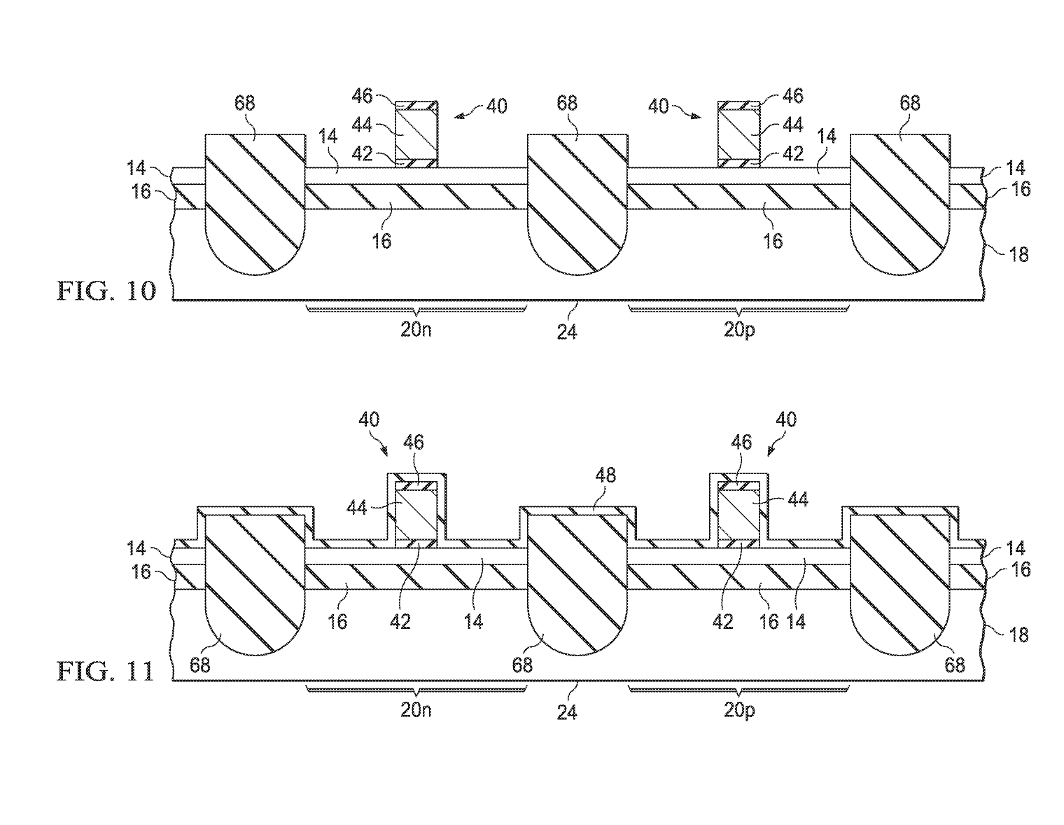

Reference is now made to FIG. 10. The wafer has been processed in accordance with FIGS. 1-9 to define a plurality of active regions separated from each other by shallow trench isolation structures 68. Two active regions are shown for illustrative purposes in FIG. 10. The active regions include an active region 20n provided for n-channel transistor fabrication and an active region 20p provided for p-channel transistor fabrication. Using techniques well known to those skilled in the art, a gate stack 40 is formed in each active region above the top semiconductor layer 14. The gate stack 40 includes a gate oxide 42 comprised of one or more insulating layers, a gate electrode 44 formed of one or more semiconductive or metal layers, and a gate cap 46 formed of one or more masking layers.

FIG. 11 shows the deposit of a spacer layer 48 over the wafer. This deposit is a blanket conformal deposit. In a preferred embodiment, the material of the spacer layer 48 is silicon nitride (SiN). Any suitable deposition technique as known to those skilled in the art can be used to deposit the spacer layer 48. In an embodiment, the gate cap 46 and spacer layer 48 are both formed of silicon nitride (SiN).

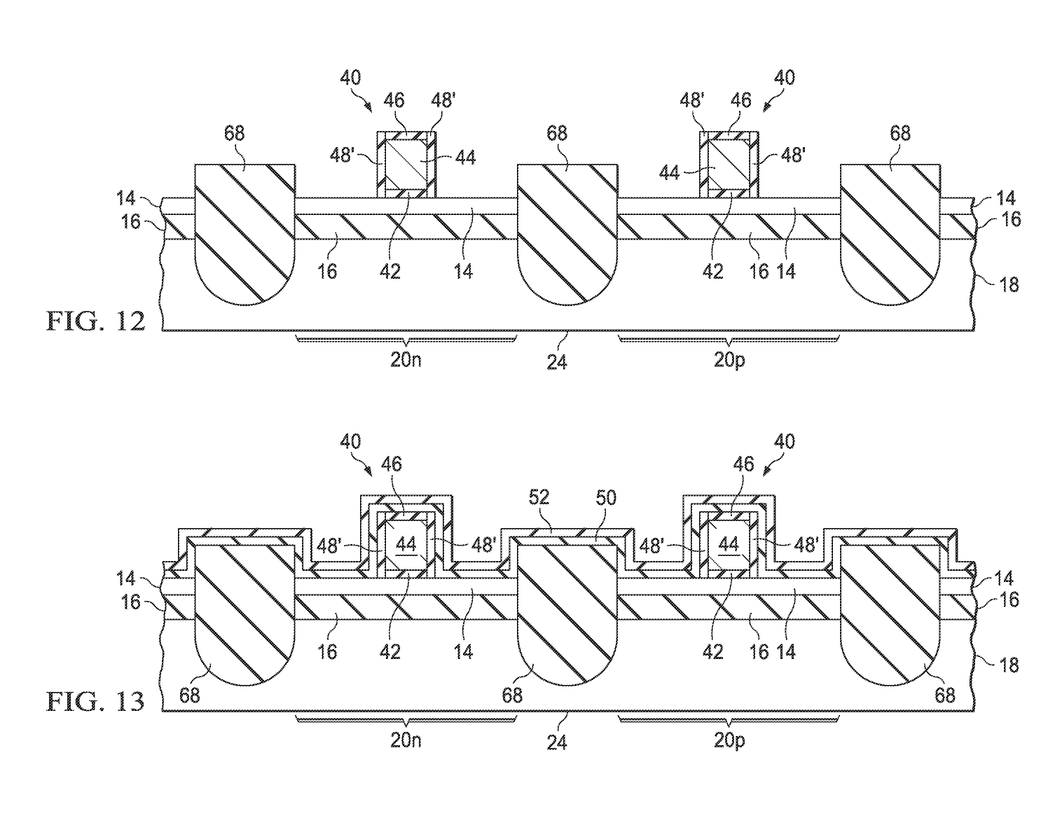

An anisotropic etch (for example, RIE) is then performed to remove the spacer layer 48. At least one exception with respect to this removal is that the etch will not remove the material of layer 48 from the side walls of the gate stack 40. The remaining portions of the spacer layer 48 accordingly form sidewall spacers 48′ for the transistor gate structures. The result of the etching process is shown in FIG. 12.

FIG. 13 shows the deposit of a conformal silicon oxide (SiO) or silicon dioxide (SiO₂) layer 50 over the wafer followed by the deposit of a conformal silicon nitride (SiN) layer 52 over the wafer. Any suitable deposition technique may be used for these deposits. For example, the chemical vapor deposition process may be used to deposit the layer 50 and the atomic layer deposition (ALD) process may be used to deposit the layer 52. The layer 50 may have a thickness of about 3 nm to 8 nm and the layer 52 may have a thickness of about 3 nm to 4 nm.

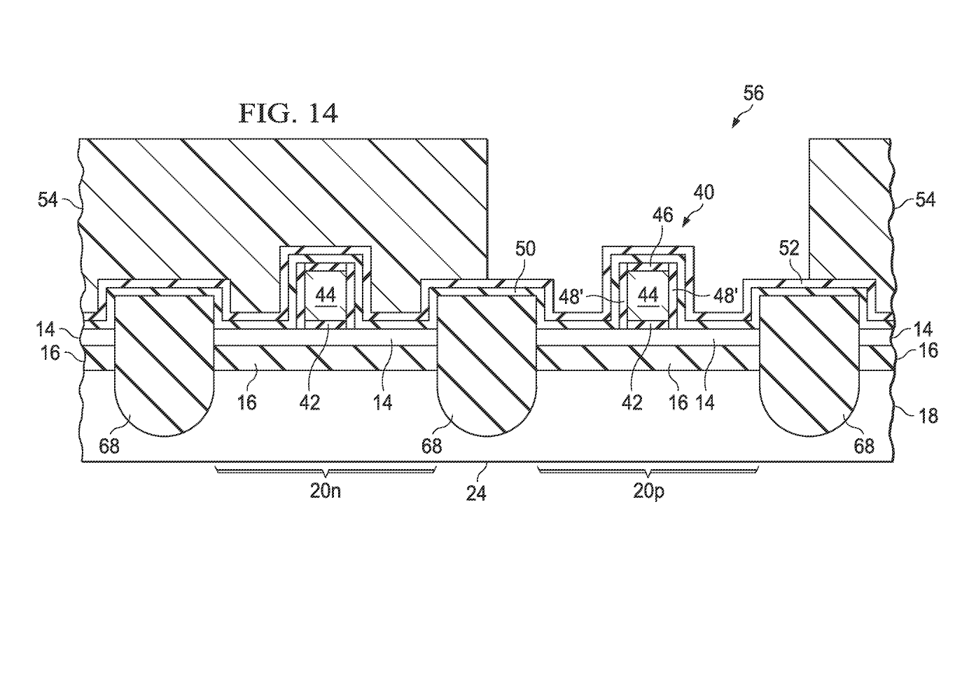

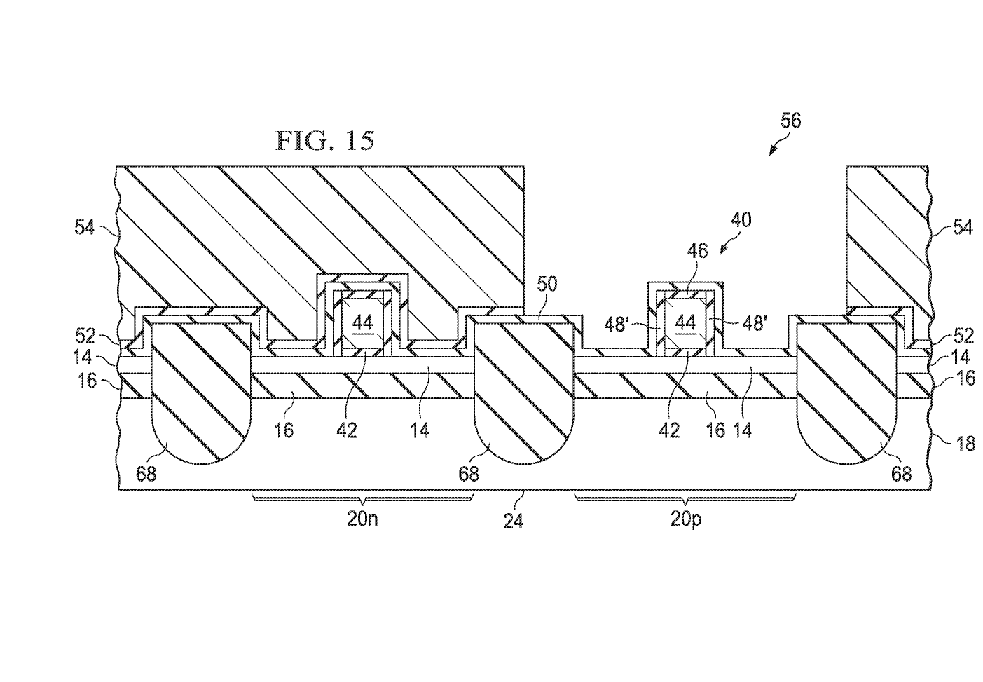

With reference to FIG. 14, a mask material 54 is then deposited and lithographically processed to provide an opening 56 over the region 20p. The opening 56 exposes the layer 52. Through the opening 56, a stripping process is performed to remove the exposed layer 52 and stop at the layer 50. The stripping process may, for example, comprise an isotropic etch. More specifically, a WET or RIE process may be used.

The mask material 54 is then removed. A consequence of the mask removal is the removal of the layer 50 in the region 20p. This will expose the top semiconductor layer 14. The layer 52 present in the region 20n over layer 50 prevents layer 50 from being removed.

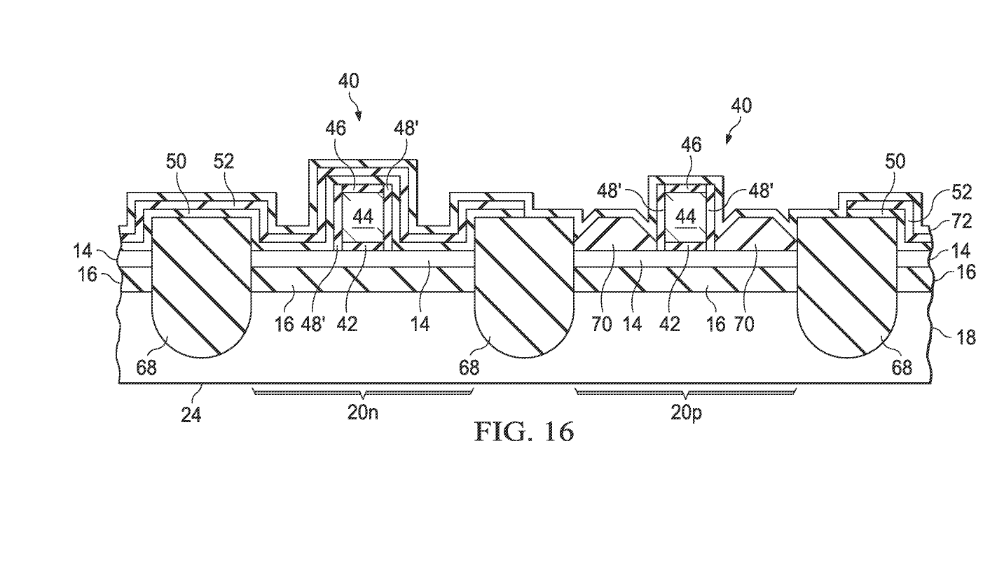

Using an epitaxial process tool, an epitaxial growth process as known in the art is performed to grow a silicon-germanium (SiGe) layer 70 on the top semiconductor layer 14 in the area adjacent the gate stack 40. This silicon-germanium (SiGe) layer 70 may be doped as required for the transistor application (for example, including a boron dopant). The thickness of the silicon-germanium (SiGe) layer 70 is, for example, about 20 nm to 30 nm. In its position adjacent the gate stack 40, the epitaxially grown silicon-germanium (SiGe) layer 70 defines raised source-drain structures for the p-channel transistor in region 20p. It will be noted that the spacer 48′ serves to ensure that the raised source-drain is isolated from the conductive material of the gate stack 40. The epitaxy is followed by the deposit of a conformal silicon nitride (SiN) layer 72 over the wafer. Any suitable deposition technique (such as the atomic layer deposition process) may be used for this deposit. The layer 72 may have a thickness of about 3 nm to 4 nm. For reasons of clarity of process explanation, the layers 52 and 72 in the region 20n are shown as separate layers, but it will be understood that the layers 52 and 72 are of a same silicon nitride (SiN) material and thus a clear delineation between layers is 52 and 72 is not likely to exist. The result is shown in FIG. 16.

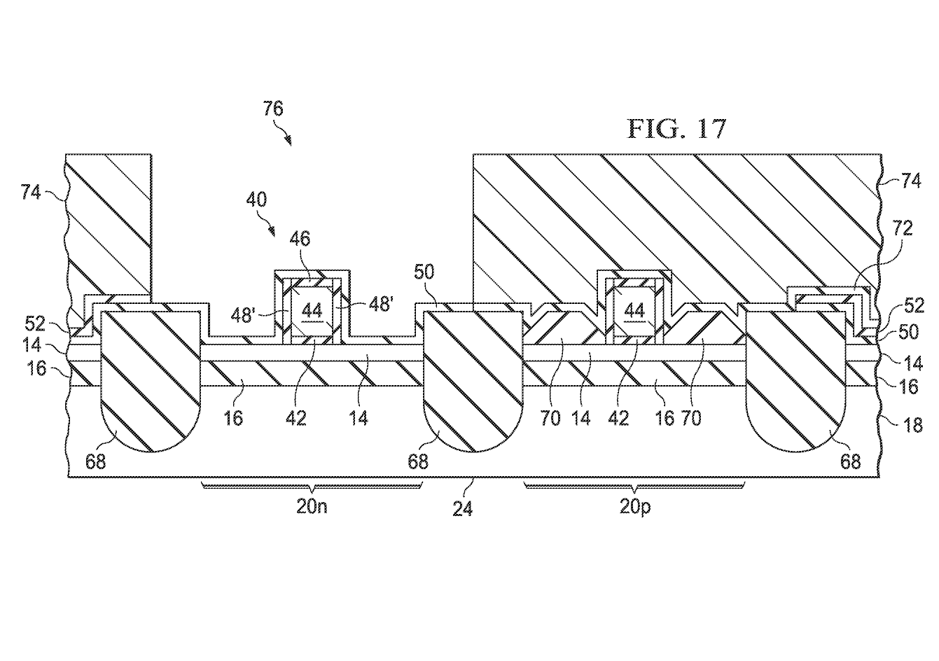

With reference to FIG. 17, a mask material 74 is then deposited and lithographically processed to provide an opening 76 over the region 20n. The opening 76 exposes the merged layer 52/72. Through the opening 76, a stripping process is performed to remove the exposed merged layer 52/72 and stop at the layer 50. The stripping process may, for example, comprise an isotropic etch. More specifically, a WET or RIE process may be used.

The mask material 74 is then removed. A consequence of the mask removal is the removal of the layer 50 in the region 20n. This will expose the top semiconductor layer 14. The layer 72 present in the region 20p over the raised source-drain structures 70 prevents damage from being inflicted on the structures 70.

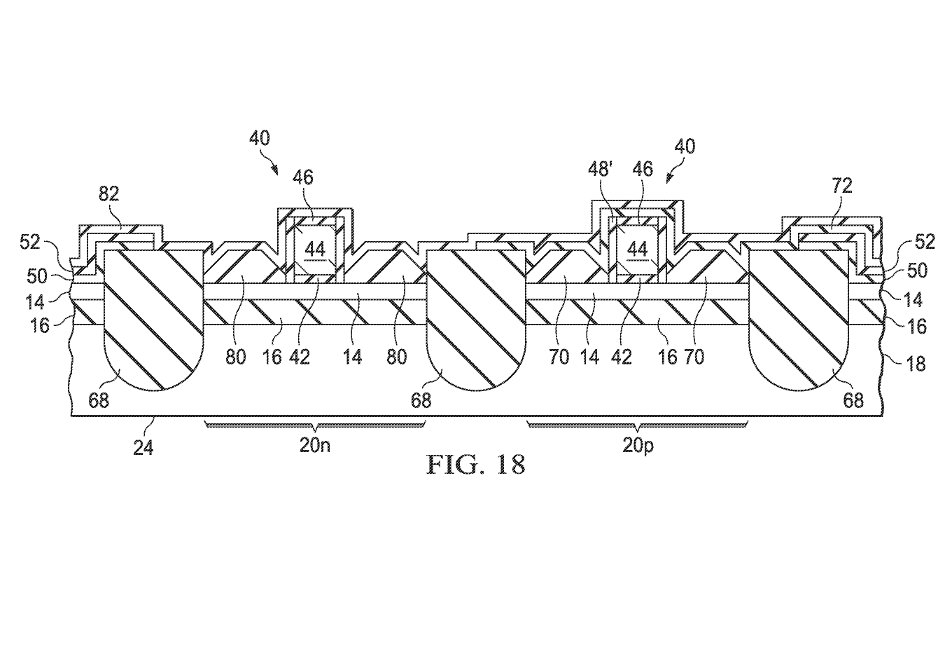

Using an epitaxial process tool, an epitaxial growth process as known in the art is performed to grow a silicon-carbon (SiC) layer 80 on the top semiconductor layer 14 in the area adjacent the gate stack 40. This silicon-carbon (SiC) layer 80 may be doped as required for the transistor application (for example, including a phosphorous dopant). The thickness of the silicon-carbon (SiC) layer 80 is, for example, about 20 nm to 35 nm. In its position adjacent the gate stack 40, the epitaxially grown silicon-carbon (SiC) layer 80 defines raised source-drain structures for the n-channel transistor. It will be noted that the spacer 48′ serves to ensure that the raised source-drain is isolated from the conductive material of the gate stack 40. The epitaxy is optionally followed by the deposit of a conformal silicon nitride (SiN) layer 82 over the wafer. Any suitable deposition technique may be used for this deposit. The layer 82 may have a thickness of about 3-4 nm. For reasons of clarity of process explanation, the layers 82 and 72 in the region 20p are shown as separate layers, but it will be understood that the layers 82 and 72 are of a same silicon nitride (SiN) material and thus a clear delineation between layers is 82 and 72 is not likely to exist. The result is shown in FIG. 18.

FIG. 18 accordingly illustrates a cross-section of a CMOS field effect transistor (FET) circuit fabricated in accordance with the disclosed process. The transistor circuit is fabricated on a silicon on insulator (SOI) substrate (for example, an ultra-thin body and buried oxide (UTBB) substrate). The substrate has a top semiconductor layer 14 over an insulating layer 16 over a bottom semiconductor substrate layer 18. Active regions 20n and 20p of the substrate 12 are defined by shallow trench isolation (STI) structures 68. Within each active region 20n and 20p, the top semiconductor layer 14 is used to form the channel of the transistor. The channel is doped as appropriate for the conductivity type of the transistor. Above the channel is formed the gate insulator 42. Although illustrated as having a single layer, it will be understood that the gate insulator 42 may be formed of multiple layers including a gate dielectric layer. For example, the gate insulator 42 may be formed of the following materials: SiO2, SiON, HfO₂ and HfSiO. The gate electrode 44 is formed over the gate insulator 42. The gate electrode 44 may comprise a polysilicon material and may be partially or fully silicided as desired for the circuit implementation. On either side of the gate electrode 44 are formed sidewall spacers 48′. It is important to note that a thickness of the spacer 48′ in the region 20n for the n-channel transistor is equal to the thickness of the spacer 48′ in the region 20p for the p-channel transistor. This accrues from the fabrication process (FIG. 11) where a single conformal deposit 48 is made over the gate stacks 40 in regions 20n and 20p to provide the material for the sidewall spacer. Furthermore, the same anisotropic etch is performed (FIG. 12) in both regions 20n and 20p to define the spacers 48′ from the deposit 48 for the transistor gate structures of each transistor type. The transistors each further include a source region and drain region. In a preferred implementation, the source region and drain region are of the raised source-drain type epitaxially grown from the top semiconductor layer 14. The raised source/drain structure may comprise silicon (Si), silicon-germanium (SiGe) and/or silicon-carbide (SiC) doped as appropriate for the conductivity type of the transistor. The source/drain regions as well as the gate polysilicon may be partially or fully silicided as desired for the circuit implementation. Because of the same thickness of the spacers 48′ in the regions 20n and 20p, the raised source-drain structures are advantageously separated from the gate electrode and channel by a same distance.

In summary, the process advantageously utilizes a common spacer material deposit along with an optimized universal etch on the regions for both n-channel transistors and p-channel transistors to define a common thickness of the sidewall spacers. A bi-layer silicon oxide and silicon nitride masking layer is used in each region type to permit stripping of the silicon nitride in a manner selective versus silicon oxide with a stop at the silicon nitride liner. The silicon oxide is removed prior to epitaxial growth of the raised source-drain structures (in the pre-epi clean) and this removal is very selective to silicon or silicon-germanium so that there is zero loss of the source drain material during fabrication.

The process described above presents a number of advantages including: a) as a result the sidewall spacer for the n-channel devices as a same thickness as the sidewall spacer for the p-channel devices; b) there is no loss with respect to the top semiconductor layer 14 in the source-drain regions because there is no damage inflicted by an RIE process, the fabrication technique instead relying on a HF or SiCoNi attack before epitaxial growth which does not attack SiN, Si or SiGe; c) scalability of the channel thickness is improved; d) there is better electrical connection with the channel; and e) there are no RIE residues and less risk of metal contamination in the source-drain regions.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A method, comprising:
forming shallow trench isolation structures on a silicon on insulator (SOI) substrate to define for a wafer a first active region for first conductivity type transistor fabrication separated from a second active region for second conductivity type transistor fabrication;
forming a first gate stack over a top semiconductor layer of the SOI substrate in the first active region and a second gate stack over the top semiconductor layer of the SOI substrate in the second active region;
conformally depositing a spacer layer on the wafer over the first and second active region;
anisotropically etching the wafer to remove the spacer layer except from sidewalls of the first and second gate stacks so as to define sidewall spacers on said first and second gate stacks;
forming an oxide layer on the wafer to cover the SOI substrate, shallow trench isolation structures, sidewall spacers and gate stacks; and
forming a nitride layer on the wafer over the oxide layer.

2. The method of claim 1, further comprising:
depositing a mask layer on the wafer over the nitride layer;
patterning the mask layer to define an opening over the first active region; and
removing the nitride layer over the first active region.

3. The method of claim 2, further comprising:
removing the mask layer over the second active region; and
removing the oxide layer over the first active region so as to expose the top semiconductor layer of the SOI substrate in the first active region while leaving the nitride layer and oxide layer in place over the second active region.

4. The method of claim 3, further comprising: epitaxially growing raised source-drain structures from the exposed the top semiconductor layer of the SOI substrate in the first active region on either side the first gate stack.

5. The method of claim 4, wherein epitaxially growing comprises growing silicon-germanium material for the raised source-drain structures.

6. The method of claim 4, wherein epitaxially growing comprises growing silicon-carbon material for the raised source-drain structures.

7. The method of claim 4, further comprising depositing a nitride layer on the wafer.

8. The method of claim 7, further comprising:
depositing an additional mask layer on the wafer over the nitride layer;
patterning the additional mask layer to define an opening over the second active region; and
removing the nitride layer over the second active region.

9. The method of claim 8, further comprising:
removing the additional mask layer over the first active region; and
removing the oxide layer over the second active region so as to expose the top semiconductor layer of the SOI substrate in the second active region while leaving the nitride layer in place over the first active region.

10. The method of claim 8, further comprising: epitaxially growing raised source-drain structures from the exposed the top semiconductor layer of the SOI substrate in the second active region on either side the second gate stack.

11. The method of claim 10, wherein epitaxially growing comprises growing silicon-germanium material for the raised source-drain structures.

12. The method of claim 10, wherein epitaxially growing comprises growing silicon-carbon material for the raised source-drain structures.

13. The method of claim 1, wherein said SOI substrate is an ultra-thin body and buried oxide (UTBB) substrate.

14. A method, comprising:
forming a first gate stack over a top semiconductor layer of a SOI substrate in a first active region;
forming a second gate stack over the top semiconductor layer of the SOI substrate in a second active region;
conformally depositing a spacer layer over the first and second active region;
anisotropically etching to remove the spacer layer except from sidewalls of the first and second gate stacks so as to define sidewall spacers on said first and second gate stacks;
forming an oxide layer to cover the SOI substrate, sidewall spacers and gate stacks; and
forming a nitride layer over the oxide layer.

15. The method of claim 14, further comprising forming shallow trench isolation structures to separate the first active region from the second active region.

16. The method of claim 14, further comprising:
depositing a mask layer over the nitride layer;
patterning the mask layer to define an opening over the first active region;
removing the nitride layer over the first active region;
removing the mask layer over the second active region; and
removing the oxide layer over the first active region so as to expose the top semiconductor layer of the SOI substrate in the first active region while leaving the nitride layer in place over the second active region.

17. The method of claim 16, further comprising: epitaxially growing raised source-drain structures from the exposed the top semiconductor layer of the SOI substrate in the first active region on either side the first gate stack.

18. The method of claim 17, further comprising:
depositing a nitride layer;
depositing an additional mask layer over the nitride layer;
patterning the additional mask layer to define an opening over the second active region;
removing the nitride layer over the second active region;
removing the additional mask layer over the first active region; and
removing the oxide layer over the second active region so as to expose the top semiconductor layer of the SOI substrate in the second active region while leaving the nitride layer in place over the first active region.

19. The method of claim 18, further comprising: epitaxially growing raised source-drain structures from the exposed the top semiconductor layer of the SOI substrate in the second active region on either side the second gate stack.

20. The method of claim 14, wherein said SOI substrate is an ultra-thin body and buried oxide (UTBB) substrate.
